(19) United States
(12) Patent Application Publication
(10) Pub. No.: US 2024/0361409 A1
(43) Pub. Date: Oct. 31, 2024

(54) MAGNETIC RESONANCE SIGNAL ACQUISITION APPARATUS

(71) Applicant: Canon Medical Systems Corporation, Otawara-shi (JP)

(72) Inventor: Hidenori TAKESHIMA, Tokyo (JP)

(73) Assignee: Canon Medical Systems Corporation, Otawara-shi (JP)

(21) Appl. No.: 18/641,501

(22) Filed: Apr. 22, 2024

(30) Foreign Application Priority Data
Apr. 26, 2023 (JP) 2023-072433

(51) Int. Cl. G01R 33/54; G01R 33/48; G01R 33/483

(52) U.S. Cl. CPC G01R 33/546; G01R 33/4828; G01R 33/4835; G01R 33/543

(57) ABSTRACT

A processing circuitry sets a first acquisition area and a second acquisition area, which are a target for signal acquisition through triaxial localization, in such a manner that the first acquisition area does not three-dimensionally overlap with the second excitation area for the second acquisition area, and the second acquisition area does not three-dimensionally overlap with the first excitation area. A pulse sequence generator acquires a first magnetic resonance signal by selectively exciting the first excitation area, and acquires a second magnetic resonance signal by selectively exciting the second excitation area.

### CROSS-REFERENCE TO RELATED APPLICATION(S)

This application is based upon and claims the benefit of priority from Japanese Patent Application No. 2023-072433, filed Apr. 26, 2023, the entire contents of which are incorporated herein by reference.

### FIELD

Embodiments described herein relate generally to a magnetic resonance signal acquisition apparatus.

### BACKGROUND

Magnetic resonance spectroscopy (MRS) acquires magnetic resonance signals by performing triaxial localization on a signal acquisition area called a “voxel of interest” (VOI) (or a “volume of interest”). A time of repetition (TR) is about 1500 ms, and TR is repeated about 64 to 128 times. The entire signal acquisition time is about 3 to 5 minutes, which is considered relatively long.

As a signal acquisition method in MRS with an aim of shortening a signal acquisition time, a method called “multi-slice localized excitation” (MUSCLE) using a magnetic resonance spectroscopic imaging (MRSI) technique in which a multi-slice method is adopted is known. With MUSCLE, only outer volume suppression (OVS) is used to acquire signals for each slice in one TR, while the freedom to choose a slice position is limited.

### BRIEF DESCRIPTION OF THE DRAWINGS

FIG. 1 is a diagram showing a configuration example of a magnetic resonance signal acquisition apparatus according to an embodiment.

FIG. 2 is a diagram showing an example of an MRS pulse sequence according to the present embodiment.

FIG. 3 is a diagram three-dimensionally showing a positional relationship between an acquisition area and an excitation area.

FIG. 4 is a diagram three-dimensionally showing

an arrangement in which a second acquisition area overlaps with an excitation area of a first acquisition area.

FIG. 5 is a diagram three-dimensionally showing an arrangement in which a second acquisition area does not overlap with an excitation area of a first acquisition area.

FIG. 6 is a diagram showing a processing procedure of MRS performed by the magnetic resonance signal acquisition apparatus. FIG. 7 is a diagram showing an example of a

setting window displayed in step S1.

FIG. 8 is a diagram showing a method of setting a first acquisition area and a second acquisition area according to a second setting example.

FIG. 9 is a diagram showing a setting screen I3 for setting a first acquisition area and a second acquisition area according to a third setting example.

FIG. 10 is a diagram illustrating a timing of switching magnetic field non-uniformity correction values.

FIG. 11 is a diagram showing a timing of applying an offset magnetic field to be superimposed for non-uniform magnetic field correction.

FIG. 12 is a diagram showing a timing of switching water-suppression controlling values.

FIG. 13 is a diagram showing a positional relationship between an OVS pulse-applied area (OVS area) and an acquisition area.

FIG. 14 is a diagram illustrating the size of an acquisition area.

### DETAILED DESCRIPTION

In general, according to one embodiment, a magnetic resonance signal acquisition apparatus includes a setting unit and an acquisition unit. The setting unit sets a first acquisition area and a second acquisition area, which are a target for signal acquisition through triaxial localization, in such a manner that the first acquisition area does not three-dimensionally overlap with a second excitation area for the second acquisition area, and the second acquisition area does not three-dimensionally overlap with a first excitation area for the first acquisition area. The acquisition unit acquires first magnetic resonance signals by selectively exciting the first excitation area and acquires second magnetic resonance signals by selectively exciting the second excitation area.

A magnetic resonance signal acquisition apparatus according to the present embodiment will be described with reference to the accompanying drawings.

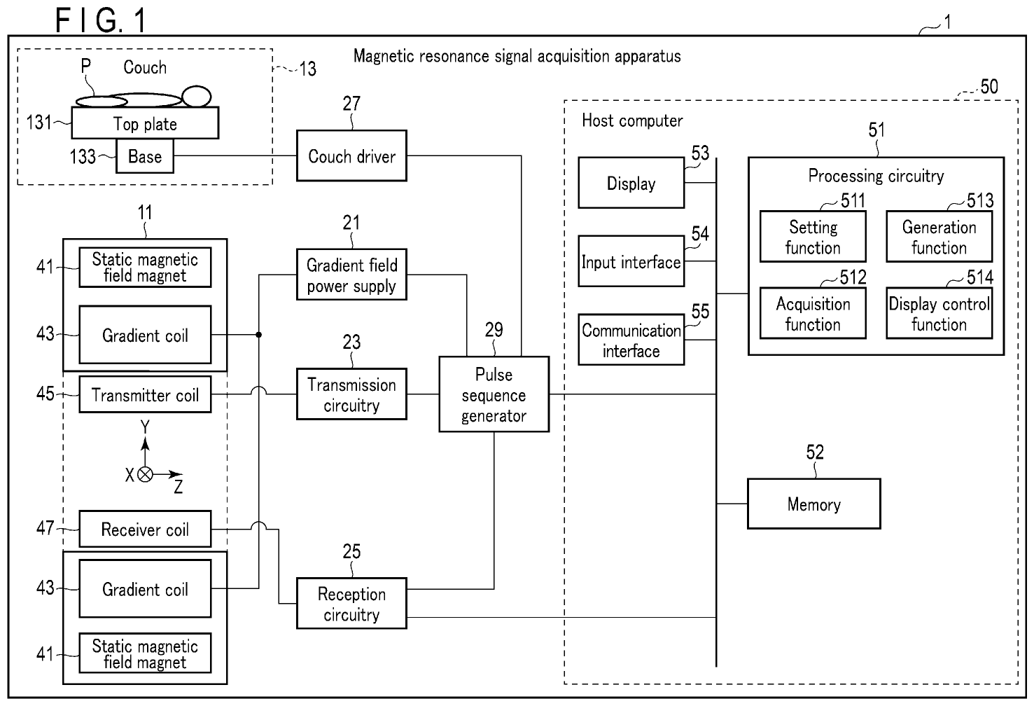

FIG. 1 is a diagram of a configuration example of

a magnetic resonance signal acquisition apparatus 1 according to the present embodiment. As shown in FIG. 1, the magnetic resonance signal acquisition apparatus 1 includes a gantry 11, a couch 13, a gradient field power supply 21, transmission circuitry 23, reception circuitry 25, a couch driver 27, pulse sequence generator 29, and a host computer 50.

The gantry 11 includes a static magnetic field magnet 41 and a gradient coil 43. The static field magnet 41 and the gradient coil 43 are accommodated in the housing of the gantry 11. A bore with a hollow shape is formed in the housing of the gantry 11. A transmitter coil 45 and a receiver coil 47 are disposed in the bore of the gantry 11.

The static magnetic field magnet 41 has a hollow approximately cylindrical shape and generates a static magnetic field inside the approximate cylinder. The static magnetic field magnet 41 uses, for example, a permanent magnet, a superconducting magnet, a normal conducting magnet, etc. The central axis of the static magnetic field magnet 41 is defined as a Z axis; an axis vertically perpendicular to the Z axis is defined as a Y axis; and an axis horizontally perpendicular to the Z axis is defined as an X axis. The X-axis, the Y-axis and the Z-axis constitute an orthogonal three-dimensional coordinate system.

The gradient coil 43 is a coil unit attached to the inside of the static magnetic field magnet 41 and formed in a hollow, approximately cylindrical shape. The gradient coil 43 generates a gradient field upon receiving a current supplied from the gradient field power supply 21. Specifically, the gradient coil 43 includes three coils corresponding respectively to the X, Y, and Z axes which are perpendicular to each other. The three coils generate gradient fields in which the magnetic field magnitude changes along the X, Y, and Z axes. The gradient magnetic along the X, Y, and Z axes are combined to generate a slice selective gradient field Gs, a phase encoding field Gp, and a frequency encoding gradient field Gr, which are perpendicular to each other, in desired directions. The slice selective gradient field Gs is used to discretionarily determine an imaging slice. The phase encoding gradient field Gp is used to change a phase of magnetic resonance signals (hereinafter “MR signals”) in accordance with a spatial position. The frequency encoding gradient field Gr is used to change a frequency of an MR signal in accordance with a spatial position. In the following description, it is assumed that the gradient direction of the slice selective gradient field Gs aligns with the Z axis, the gradient direction of the phase encoding gradient field Gp aligns with the Y axis, and the gradient direction of the frequency encoding gradient field Gr aligns with the X axis.

The gradient field power supply 21 supplies a current to the gradient coil 43 in accordance with a sequence control signal from the pulse sequence generator 29. Through the supply of the current to the gradient coil 43, the gradient field power supply 21 makes the gradient coil 43 generate gradient fields along the X-axis, the Y-axis, and the Z-axis. These gradient fields are superimposed on the static magnetic field formed by the static field magnet 41 and applied to the subject P.

The transmitter coil 45 is arranged inside the gradient coil 43 and generates a high-frequency pulse (hereinafter referred to as an RF pulse) upon receipt of a current supplied from the transmission circuitry 23.

The transmission circuitry 23 supplies a current to the transmitter coil 45 in order to apply an RF pulse for exciting target protons in the subject P to the subject P via the transmitter coil 45. The RF pulse vibrates at a resonance frequency specific to the target protons, and electrically excites those target protons. An MR signal is generated from the electrically excited target protons and is detected by the receiver coil 47. The transmitter coil 45 is, for example, a whole-body coil (WB coil). The whole-body coil may be used as a transmitter/receiver coil.

The receiver coil 47 receives an MR signal generated from the target protons that are present in the subject P as a result of the effects of the RF pulse. The receiver coil 47 includes a plurality of receiver coil elements capable of receiving MR signals. The received MR signal is supplied to the reception circuitry 25 by wiring or wirelessly. Although not shown in FIG. 1, the receiver coil 47 has a plurality of reception channels arranged in parallel. Each receiver channel includes a receiver coil element that receives MR signals, an amplifier that amplifies the MR signals, etc. An MR signal is output from each reception channel. The total number of the reception channels may be equal to, larger than, or smaller than the total number of the receiver coil elements.

The reception circuitry 25 receives an MR signal generated from the excited target protons via the receiver coil 47. The reception circuitry 25 processes the received MR signal to generate a digital MR signal. The digital MR signal can be expressed by a k-space defined by spatial frequency. Hereinafter, the digital MR signals are referred to as k-space data. k-space data is digital data in which a signal strength value of an MR signal is expressed with a time function. k-space data is supplied to the host computer 50 either by wiring or wirelessly.

The transmitter coil 45 and the receiver coil 47 described above are merely examples. A transmitter/receiver coil which has a transmit function and a receive function may be used instead of the transmitter coil 45 and the receiver coil 47. Alternatively, the transmitter coil 45, the receiver coil 47, and the transmitter/receiver coil may be combined.

The couch 13 is installed adjacent to the gantry 11. The couch 13 includes a top plate 131 and a base 133. The subject P is placed on the top plate 131. The base 133 supports the top plate 131 slidably along each of the X-axis, the Y-axis, and the Z-axis. The couch driver 27 is accommodated in the base 133. The couch driver 27 moves the top plate 131 under the control of the pulse sequence generator 29. The couch driver 27 may include, for example, any motor such as a servo motor or a stepping motor.

The pulse sequence generator 29 includes, as hardware resources, a processor such as a central processing unit (CPU) or a micro processing unit (MPU), and a type of memory such as read only memory (ROM) and random access memory (RAM). The pulse sequence generator 29 controls the gradient field power supply 21, the transmission circuitry 23, and the reception circuitry 25 synchronously based on signal acquisition conditions that are set by the setting function 511 of the processing circuitry 51, and acquires MR signals originating from the subject P. The pulse sequence generator 29 is an example of the acquisition unit.

The pulse sequence generator 29 according to the present embodiment performs signal acquisition for MR spectroscopy (MRS), which is a type of chemical shift measurement. Chemical shift measurement is a technique of measuring a chemical shift that is a slight difference between resonance frequencies of a targeted proton, such as a hydrogen atomic nuclei etc., which is caused by different chemical environments. An amount of substance of metabolite included in an acquisition target area can be measured by analyzing an MR signal strength of each chemical shift value.

The pulse sequence generator 29 performs signal acquisition on an acquisition target area that is set inside the body of the subject Pl, in accordance with an MRS pulse sequence based on the signal acquisition conditions. Performing an MRS pulse sequence causes generation of an MR signal, such as a free induction decay (FID) signal or a spin echo signal, from the body of the subject P. The reception circuitry 25 receives an observable MR signal via the receiver coil 47, and performs signal processing on the received MR signal to acquire data relating to the measurement target.

As shown in FIG. 1, the host computer 50 is a computer having a processing circuitry 51, a memory 52, a display 53, an input interface 54, and a communication interface 55. Data communications between the processing circuitry 51, the memory 52, the display 53, the input interface 54, and the communication interface 55 are performed via a bus.

The processing circuitry 51 includes a processor such as a CPU, etc. as hardware resources. The processing circuitry 51 functions as the main unit of the MR signal acquisition apparatus 1. For example, the processing circuitry 51 executes various programs to realize a setting function 511, an acquisition function 512, a generation function 513, and a display control function 514.

The processing circuitry 51 sets, through realization of the setting function 511, signal acquisition conditions in MRS of the present embodiment. Examples of the signal acquisition conditions are an acquisition area, and a position of an excitation area associated with the acquisition area. Two or more acquisition areas and two or more excitation areas are set in the present embodiment. Specifically, the processing circuitry 51 sets the first acquisition area and the second acquisition area, which are a target for signal acquisition through triaxial localization, in such a manner that the first acquisition area does not three-dimensionally overlap with the second excitation area for the second acquisition area, and the second acquisition area does not three-dimensionally overlap with the first excitation area for the first acquisition area. The processing circuitry 51 sets, together with the first acquisition area, the first excitation area consisting of three band areas that are triaxially orthogonal to each other in the first acquisition area, and sets, together with the second acquisition area, the second excitation area consisting of three band areas that are triaxially orthogonal to each other in the second acquisition area. The number of the acquisition areas that can be set in the present embodiment is not limited to two and may be three or more.

Examples of the signal acquisition conditions are, aside from the positions of the acquisition areas and the excitation areas, a type of basic MRS sequence, a correction value for magnetic field non-uniformity correction, a control value for water suppression, OVS, a time of repetition (TR), an echo time (TE), the number of times of integration (number of excitations, NEX) a spectrum width, the number of samplings, and an area selective pulse, etc. The imaging conditions may be automatically set manually by a user or by an algorithm.

The processing circuitry 51, through realization of the acquisition function 512, instructs the pulse sequence generator 29 to perform MR spectroscopy based on the signal acquisition conditions set by the setting function 511. The pulse sequence generator 29 performs MR spectroscopy, following the instructions from the processing circuitry 51. In the MR spectroscopy, the pulse sequence generator 29 alternately repeats the signal acquisition in the first acquisition area and the signal acquisition in the second acquisition area. At this time, the pulse sequence generator 29 acquires a first MR signal by selectively exciting the first excitation area, and acquires a second MR signal by selectively exciting the second excitation area. The “first MR signal” means an MR signal expected to originate from the first acquisition area, and the “second MR signal” means an MR signal expected to originate from the second acquisition area. The first and second MR signals are received by the reception circuit 25 and digitally converted. The digitally converted first and second MR signals are transmitted to the processing circuitry 51. The processing circuitry 51 acquires the first and second MR signals transmitted from the reception circuitry 25. The acquisition function 512 is an example of the acquisition unit.

The processing circuitry 51, through realization of the generation function 513, generates a first spectrum indicating a signal strength distribution of the first MR signal for each chemical shift frequency based on the first MR signal acquired by the acquisition function 512, and generates a second spectrum indicating a signal strength distribution of the second MR signal for each chemical shift frequency based on the second MR signal acquired by the acquisition function 512. Furthermore, the processing circuitry 51 may estimate an absolute value and/or a relative value, etc. of an amount of substance of metabolite included in the first and second acquisition areas based on the first and second spectra. The generation function 513 is an example of the generation unit.

Through realization of the display control function 514, the processing circuitry 51 causes a display device such as the display 53 to display various types of information. As an example, the processing circuitry 51 causes the display device to display a setting screen for setting the acquisition area and/or the excitation area. The display control function 514 is an example of the display control unit.

The memory 52 is a storage apparatus such as a hard disk drive (HDD), a solid state drive (SSD), an integrated circuitry storage apparatus, or the like that stores various information. The memory 52 may be a drive that reads and writes various types of information from and in a portable storage medium such as a CD-ROM drive, a DVD drive, or a flash memory.

The display 53 displays various types of information in accordance with a control by the display control function 514. Examples of appropriate displays 53 that can be used include a CRT display, a liquid crystal display, an organic EL display, an LED display, a plasma display, or any other display known in the art.

The input interface 54 includes an input apparatus that receives various commands from the user. Examples of the input apparatus that can be used include a keyboard, a mouse, various switches, a touch screen, a touch pad, and the like. The input device is not limited to a device with a physical operation component, such as a mouse or a keyboard. For example, examples of the input interface 54 also include electrical signal processing circuitry that receives an electrical signal corresponding to an input operation from an external input apparatus provided separately from the magnetic resonance signal acquisition apparatus 1, and outputs the received electrical signal to various types of circuitry. The input interface 54 may be a speech recognition device that converts audio signals acquired by a microphone into command signals.

The communication interface 55 is an interface connecting the magnetic resonance signal acquisition apparatus 1 with a workstation, a picture archiving and communication system (PACS), a hospital information system (HIS), a radiology information system (RIS), and the like via a local area network (LAN) or the like. The communication interface 55 transmits and receives various types of information to and from the connected workstation, PACS, HIS, and RIS.

Next, an example of the operation of the magnetic resonance signal acquisition apparatus 1 according to the present embodiment is explained. First, an MRS pulse sequence according to the present embodiment is explained. The MRS according to the present embodiment performs signal acquisition on two or more acquisition areas; however, the number of acquisition areas is two in the example described hereinafter. The signal acquisition for three or more acquisition areas can be performed in a manner similar to the signal acquisition for two acquisition areas

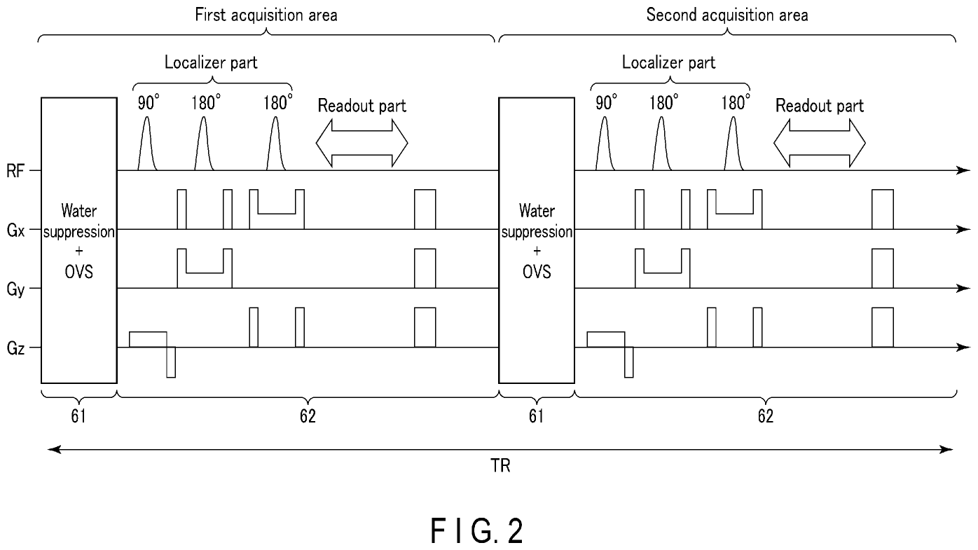

FIG. 2 is a diagram showing an example of an MRS pulse sequence according to the present embodiment. As shown in FIG. 2, in an MRS pulse sequence according to the present embodiment, a signal acquisition in the first acquisition area and a signal acquisition in the second acquisition area are alternately repeated. A pulse sequence for each acquisition area includes a preprocessing part 61 for water suppression and OVS and a signal acquisition part 62 that follows the preprocessing part 61. The preprocessing part 61 includes a water suppression sequence for suppressing signals originating from free water included in the acquisition area, and an OVS sequence for OVS for suppressing signals originating from the OVS area.

In the signal acquisition part 62, a basic sequence of the MRS pulse sequence is performed. As the basic sequence, PRESS (point resolved spectroscopy), STEAM (stimulated echo acquisition mode), LASER (localization by adiabatic selective refocusing), semi-LASER, SPECIAL (spin echo full intensity acquired localized spectroscopy), and their advanced techniques may be used. Specifically, the signal acquisition part 62 includes a localizer part for selecting an acquisition area and a readout part for acquiring an MR signal. In the localizer part, a gradient field pulse for selecting an area in the Z-axis direction and a 90-degree excitation pulse superimposed thereon are applied, a gradient field pulse for selecting an area in the Y-axis direction and a 180-degree refocusing pulse superimposed thereon are successively applied, and a gradient field pulse for selecting an area in the X-axis direction and a 180-degree refocusing pulse superimposed thereon are then applied. A three-dimensional spatial area intersecting with the excitation area excited by the 90-degree excitation pulse, the excitation area excited by the first 180-degree refocusing pulse, and the excitation area excited by the second 180-degree refocusing pulse is an acquisition area. Such an area-selecting operation is called “triaxial localization”.

In the readout part, a readout gradient field is applied and an MR signal is received by the reception circuitry 25. After an MR signal is received, a spoiler pulse is applied to each of the X-axis, Y-axis, and Z-axis directions to reduce magnetization remaining in the excitation area.

As shown in FIG. 2, a signal acquisition in the first acquisition area and a signal acquisition in the second acquisition area are alternately repeated. After the signal acquisition in the first acquisition area, a signal acquisition in the second area is performed before saturated magnetization in the first excitation area accompanying the first acquisition area is completely recovered. After the signal acquisition in the second acquisition area, a signal acquisition in the first area is performed before saturated magnetization in the second excitation area associated with the second acquisition area is completely recovered. It is thereby possible to shorten a signal acquisition time for the signal acquisition in the first acquisition area and for the signal acquisition in the second acquisition area. With the signal acquisition method according to the present embodiment, a time equivalent to a sum of a signal acquisition time for the first acquisition area and that for the second acquisition area is TR.

Next, the acquisition areas and the excitation areas according to the present embodiment are described.

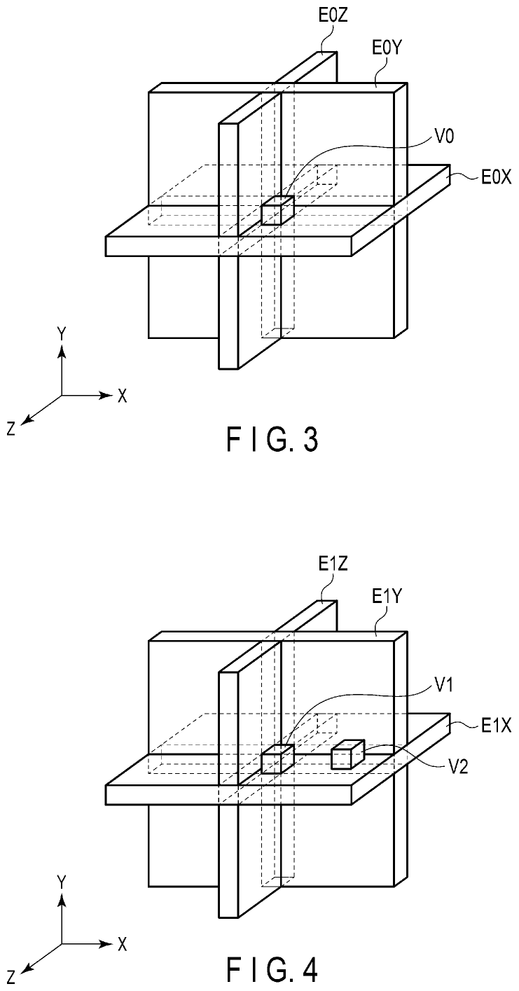

FIG. 3 is a diagram three-dimensionally showing a

positional relationship between an acquisition area V0 and an excitation area E0. The acquisition area V0 is a spatial area of the MR signal acquisition target selected by triaxial localization. Suppose the acquisition area V0 is defined by a single voxel. The acquisition area V0 may be referred to as a “volume of interest” (VOI). The excitation area E0 is a band-shaped (slab-shaped) spatial area excited by triaxial localization for spatially selecting the acquisition area V0. Specifically, the excitation area E0 has a slab-shaped excitation area E0Z relating to the gradient direction Z of the slice selective gradient field, a slab-shaped excitation area E0Y relating to the gradient direction Z of the phase encoding gradient field, and a slab-shaped excitation area E0X relating to the gradient direction X of the readout gradient field. A three-dimensional area in which the excitation areas E0Z, E0Y, and E0X intersect with each other is set as the acquisition area V0.

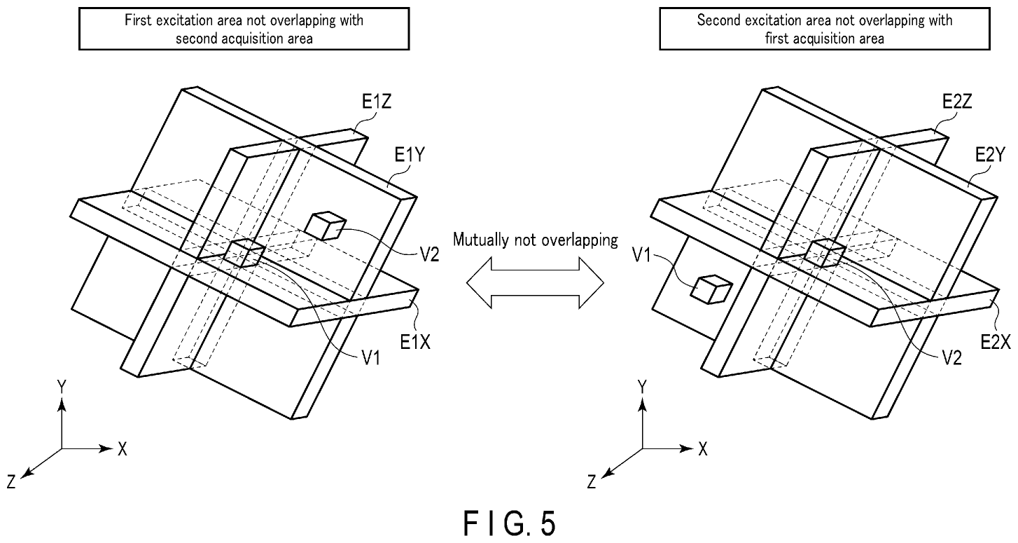

Next, problems in setting a plurality of acquisition areas are described. FIG. 4 is a diagram three-dimensionally showing an arrangement in which the second acquisition area V2 overlaps with the excitation area E1X of the first acquisition area V1. Suppose the second acquisition area V2 partially overlaps with the excitation area E1X relating to the X-axis direction of the acquisition area V1 as shown in FIG. 4. As described above, since the signal acquisition in the first acquisition area V1 and the signal acquisition in the second acquisition area V2 are alternately repeated when signal acquisition is performed, the excitation area E1X is excited prior to the signal acquisition in the second acquisition area V2. At the time of acquiring a second MR signal relating to the second acquisition area V2 that overlaps with the excitation area E1X, if magnetization remains in the excitation area E1X, the signal strength of the second MR signal reduces to a greater degree than the case where magnetization does not remain. In other words, if an acquisition area overlaps with an excitation area associated with another acquisition area, there is a possibility that an MR signal having a correct strength may not be acquired.

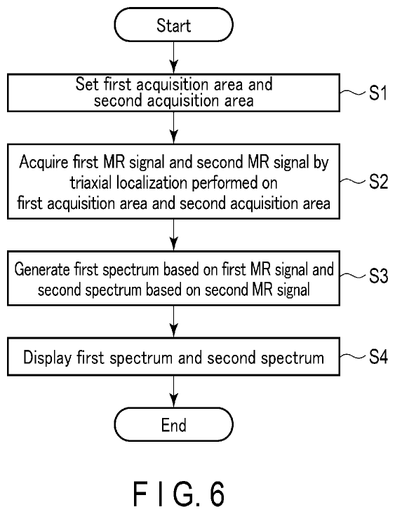

FIG. 5 is a diagram three-dimensionally showing

an arrangement in which the second acquisition area V2 does not overlap with the excitation area E1 of the first acquisition area V1. As shown in FIG. 5, the first acquisition area V1 and the second acquisition area V2 are in the same positional relationship as illustrated in FIG. 4. In other words, the second acquisition area V2 is arranged at a position at which it overlaps with the excitation area E1X if the excitation area E1X is arranged in parallel to the X axis, and the first acquisition area V1 is arranged at a position at which it overlaps with the excitation area E2X if the excitation area E2X is arranged in parallel to the X axis.

As shown in FIG. 5, through realization of the setting function 511, the processing circuitry 51 sets the first acquisition area V1 and the second acquisition area V2, which are a target for signal acquisition through triaxial localization, in such a manner that the first acquisition area V1 does not overlap three-dimensionally, nor two-dimensionally, with the second excitation areas E2X, E2Y, and E2Z for the second acquisition area V2, and the second acquisition area V2 does not overlap three-dimensionally, nor two-dimensionally, with the first excitation areas E1X, E1Y, and E1Z for the first acquisition area V1. Specifically, the first excitation areas E1X, E1Y, and E1Z and/or the second excitation areas E2X, E2Y, and E2Z are three-dimensionally rotated (in other words, made to be oblique) from an initial three-dimensional angle to a specific three-dimensional angle so that the first acquisition area V1 does not overlap with the second excitation areas E2X, E2Y, and E2Z and the second acquisition area V2 does not overlap with the first excitation areas E1X, E1Y, and E1Z.

The “three-dimensional angle” is defined by a combination of an angle with respect to the X axis, an angle with respect to the Y axis, and an angle with respect to the Z axis. The “initial three-dimensional angle” means an initially set three-dimensional angle, and means that, for example, each of the angle with respect to the X axis, the angle with respect to the Y axis, and the angle with respect to the Z axis is 0 degrees. It suffices that the “specific three-dimensional angle” should be discretionarily selected from three-dimensional angles (hereinafter “non-overlapping angles”) that allow the first acquisition area V1 to be arranged without overlapping with the second excitation areas E2X, E2Y, and E2Z and allow the second acquisition area V2 to be arranged without overlapping with the first excitation areas E1X, E1Y, and E1Z. A non-overlapping angle may be searched by increasing an initial three-dimensional angle by a predetermined three-dimensional angle or a random angle, or through a discretionarily selected optimization technique such as Bayes optimization, etc., or through a technique of searching from manually designated three-dimensional angles. The “specific three-dimensional angle” may be called an “oblique angle”.

By setting the first acquisition area V1 and the second acquisition area V2 in the second excitation areas E2X, E2Y, and E2Z and the first excitation areas E1X, E1Y, and E1Z, respectively, without overlapping with the second excitation areas E2X, E2Y, and E2Z and the first excitation areas E1X, E1Y, and E1Z, it is possible to reduce a signal loss of the first MR signal caused by magnetization saturation due to an excitation of the second excitation areas E2X, E2Y, and E2Z, and a signal loss of the second MR signal caused by magnetization saturation due to an excitation of the first excitation areas E1X, E1Y, and E1Z.

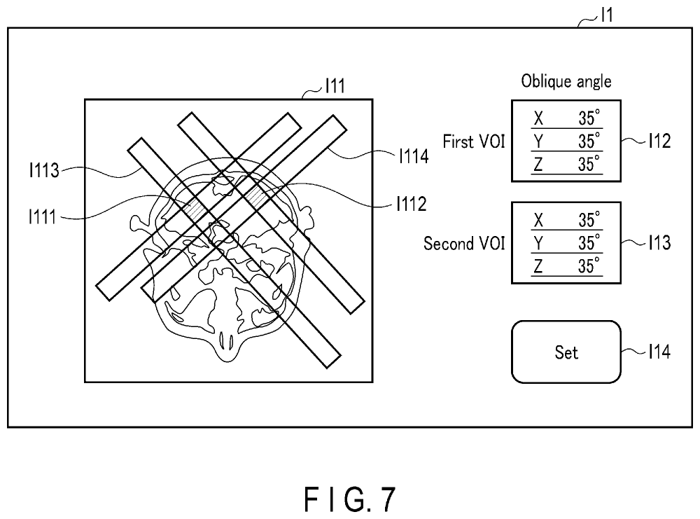

Next, an example of the operation of the magnetic resonance signal acquisition apparatus 1 according to the present embodiment is explained. FIG. 6 is a diagram showing a processing procedure of MRS performed by the magnetic resonance signal acquisition apparatus 1. As shown in FIG. 6, the processing circuitry 51 sets, through realization of the setting function 511, a first acquisition area and a second acquisition area (step S1). In step S1, the processing circuitry 51 sets the first acquisition area and the second acquisition area via the user interface screen (hereinafter, a “setting screen”). The setting screen is caused to be displayed on the display 53 by the display control function 514 of the processing circuitry 51. The processing circuitry 51 sets the first acquisition area and the second acquisition area based on a user instruction that is input via the user interface screen. The processing circuitry 51 sets, together with the first acquisition area, the first excitation area consisting of three band areas that are triaxially orthogonal to each other in the first acquisition area, and sets, together with the second acquisition area, a second excitation area consisting of three band areas that are triaxially orthogonal to each other in the second acquisition area. The first and second excitation areas are determined in accordance with the positions and oblique angles of the first and second acquisition areas; in other words, the first and second acquisition areas are determined by the positions and oblique angles of the first and second excitation areas. In the description hereinafter, the first and second acquisition areas are determined by the positions and oblique angles of the first and second excitation areas, unless otherwise noted.

FIG. 7 is a diagram showing an example of the setting screen I1. As shown in FIG. 7, an MR image I11, a display box I12, a display box I13, and a setting button I14 are displayed in the setting screen I1. As the MR image I11, it suffices that an MR image discretionarily generated in advance is displayed as an image for setting an acquisition area. FIG. 7 shows an axial cross-sectional (XY sectional) image of a head as the MR image I11. On the MR image I11, a marker I111 indicating the first acquisition area (hereinafter a “first VOI marker”) and a marker I112 indicating the second acquisition area (hereinafter a “second VOI marker”) are superimposed. On the MR image I11, a marker I113 indicating the first excitation area associated with the first acquisition area (hereinafter, a “first excitation area marker”) and a marker I114 indicating the second excitation area associated with the second acquisition area (hereinafter, a “second excitation area marker”) may be superimposed. The first VOI marker I111, the second VOI marker I112, the first excitation area marker I113, and the second excitation area marker I114 can be moved, rotated, expanded, or contracted via the input interface 54. The MR image I11 is not limited to a cross-sectional image; a volume rendering image may be displayed. In this case, the markers I111, I112, I113, and I114 are three-dimensionally displayed.

In the display box I12, an oblique angle of the first excitation area associated with the first acquisition area (first VOI) is displayed. In the display box I13, an oblique angle of the second excitation area associated with the second acquisition area (second VOI) is displayed. In FIG. 7, as an example, the oblique angles of the first excitation area and the second acquisition area are 35 degrees with respect to the X axis, the Y axis, and the Z axis, respectively. The oblique angles displayed in the display box I12 and the display box I13 are discretionarily changeable via the input interface 54. The first VOI marker I111 and the second VOI marker I112 are rotated in response to an operation to change an oblique angle that is input in the display box I12 and the display box I13. The setting button I14 is a GUI component for confirming the positions of the first acquisition area and the second acquisition area in the setting screen I1 and the oblique angle. If the setting button I14 is pressed by an operator via the input interface 54, the processing circuitry 51 determines three-dimensional positions and oblique angles of the first acquisition area, the second acquisition area, the first excitation area, and the second excitation area based on the positions and the oblique angles of the first VOI marker I111, the second VOI marker I112, the first excitation area marker I113, and the second excitation area marker I114 superimposed on the MR image I11.

Hereinafter, specific examples of setting of the first acquisition area and the second acquisition area are described. As the first setting example, the processing circuitry 51 restricts the oblique angle as an initial setting, and sets the first acquisition area and the second acquisition area within the restriction. Specifically, the processing circuitry 51 first determines an initial oblique angle in accordance with a discretionarily selected algorithm or an operator's designated angle.

Next, as shown in FIG. 7, the processing circuitry 51 causes the first acquisition area and the second acquisition area that are three-dimensionally tilted by the determined oblique angle to be displayed. Specifically, the processing circuitry 51 causes the first VOI marker indicating the first acquisition area and the first excitation area marker to be displayed at the first initial positions, and the second VOI marker indicating the second acquisition area and the second excitation area marker to be displayed at the second initial positions. At this time, the processing circuitry 51 causes the first VOI marker, the first excitation area marker, the second VOI marker, and the second excitation area marker to be displayed with a tilt by the determined initial oblique angle. The operator can change the positions of the first and second acquisition areas at their discretion by operating the first and second VOI markers. The operator can also change the oblique angle of the first excitation area after the fact by changing the value in the display box I12 to a discretionarily selected value, and the oblique angle of the second excitation area by changing the value in the display box I13 to a discretionarily selected value. If the setting button I14 is pressed via the input interface 54, the processing circuitry 51 sets the first acquisition area, the first excitation area, the second acquisition area, and the second excitation area corresponding to the positions and the oblique angles of the first VOI marker, the first excitation area marker, the second VOI marker, and the second excitation marker.

Next, the second setting example is described. In the second setting, the processing circuitry 51 sets the positions of the first acquisition area and the second acquisition area based on a user instruction that is input via the setting screen as an initial setting. If the first acquisition area overlaps with the second excitation area and/or the second acquisition area overlaps with the first excitation area, the processing circuitry 51 automatically adjusts an oblique angle(s) of the first acquisition area and/or the second acquisition area so that the first acquisition area and/or the second excitation area do(es) not overlap with the second acquisition area and/or the first excitation area.

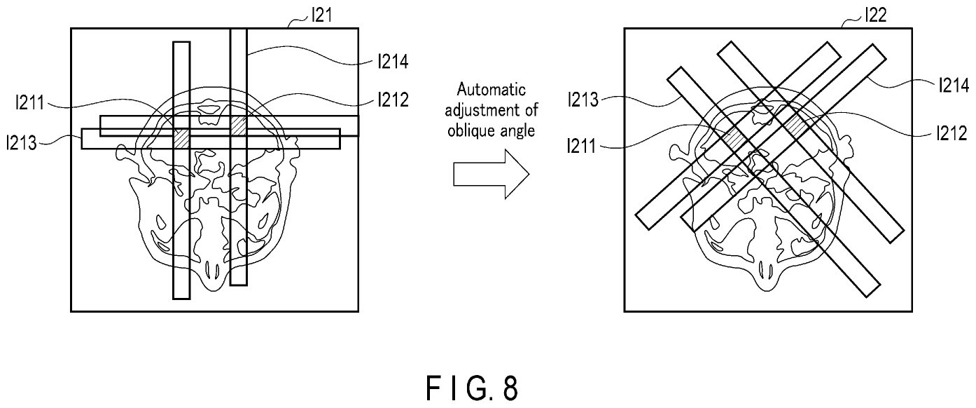

FIG. 8 is a diagram showing a method of setting a first acquisition area and a second acquisition area according to a second setting example. As shown in the left diagram in FIG. 8, the first VOI marker I211, the first excitation area marker I21, a second VOI marker I212, and a second excitation area marker I214, which correspond to the initial first acquisition area, the first excitation area, the second acquisition area, and the second excitation area, respectively, are displayed in the MR image I21. Suppose the position of the first acquisition area (first position) and the position of the second acquisition area (second position) are designated in the initial oblique angle, in such a manner that the first VOI marker I211 overlaps with the second excitation area marker I214 and the second VOI marker I212 overlaps with the first excitation area marker I213.

If the first position of the first acquisition area and the second position of the second acquisition area are designated, the processing circuitry 51 determines whether or not the first acquisition area overlaps with the second excitation area and/or the second acquisition area overlaps with the first excitation area. If it is determined that there are no overlaps, the processing circuitry 51 sets the initial three-dimensional angle as the final oblique angle of the first acquisition area and the second acquisition area. If it is determined that there are overlaps, the processing circuitry 51 searches for a three-dimensional angle (permitted angle) in which the first acquisition area does not overlap with the second excitation area and the second acquisition area does not overlap with the first excitation area at the designated first position and second position, and sets the permitted angle as a final oblique angle of the first acquisition area and the second acquisition area. If there are multiple permitted angles, a discretionarily selected permitted angle may be set as a final oblique angle. As shown on the right side of FIG. 8, the first VOI marker I211, the first excitation area marker I213, the second VOI marker I212, and the second excitation area marker I214 are displayed on the MR image I22 in accordance with the final oblique angle.

Next, the third setting example is described. Since the area in the vicinity of each acquisition area is strongly influenced by excitation of the acquisition areas, it cannot be expected that an MR signal from an expected signal strength can be acquired from the neighboring area. It is desirable to manage such a spatial area from which an acquisition of an MR signal having an expected signal strength cannot be expected as an area in which a signal acquisition is physically impossible. In the third setting example, the processing circuitry 51 bars setting of the first acquisition area and the second acquisition area in the physical signal acquisition impossible area. The signal acquisition impossible area is set in a spatial area having a specific width that covers each of the first acquisition area and the second acquisition area.

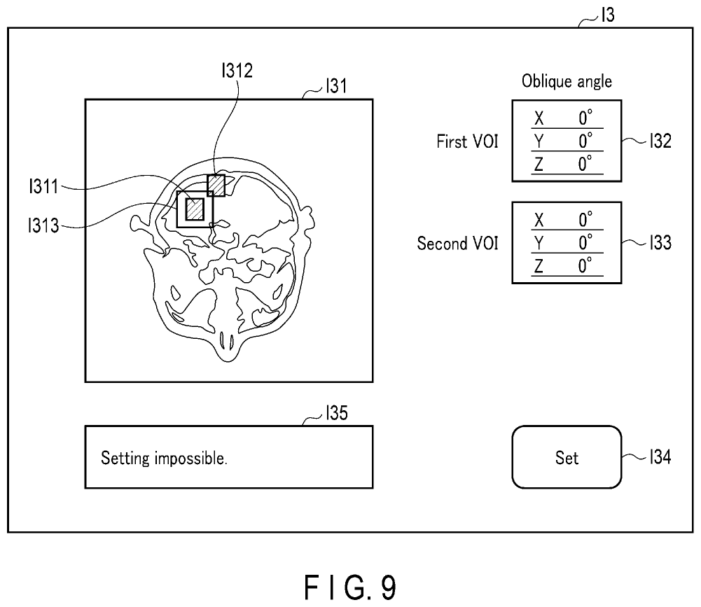

FIG. 9 is a diagram showing a setting screen I3 for setting a first acquisition area and a second acquisition area according to a third setting example. As shown in FIG. 9, the setting screen I3 displays an MR image I31, a display box I32, a display box I33, a setting button I34, and a display box I35. The MR image I31, the display box I32, the display box I33, and the setting button I34 are the same as the MR image I11, the display box I12, the display box I13, and the setting button I14 in FIG. 7, respectively. Suppose the oblique angles of the first excitation area and the second excitation area are 0 degrees in FIG. 9.

If the position of the first acquisition area is designated, the processing circuitry 51 causes the first VOI marker I311 to be displayed at the designated position, as shown in FIG. 9. In parallel to this processing, the processing circuitry 51 specifies a signal acquisition impossible area due to the first acquisition area and causes the marker I313 indicating the signal acquisition impossible area (hereinafter “acquisition impossible area marker”) to be displayed. It suffices that the signal acquisition impossible area includes the first acquisition area, and that the width of the signal acquisition impossible area is set to ⅕ of the width of the first acquisition area. The width of the signal acquisition impossible area may be set to an arbitrarily determined value. The processing circuitry 51 bars the setting of other acquisition areas within the signal acquisition impossible area. Specifically, the processing circuitry 51 bars setting the second acquisition area in an area that does not overlap with the signal acquisition impossible area stemming from the first acquisition area. For example, if the position of the second acquisition area is designated within the acquisition impossible area marker I313, the processing circuitry 51 causes a warning message, such as “setting cannot be done”, to be displayed in the display box I35 so as to prompt an operator to designate a position outside the acquisition impossible area marker.

The display of the acquisition impossible area marker I313 enables the operator to visually check the position of the second VOI marker I312 with respect to the acquisition impossible area marker I313. The processing circuitry 51 may set the signal acquisition impossible area of the second acquisition area. In this case, the processing circuitry 51 bars the setting of the first acquisition area in the area that does not overlap with the area in which signal acquisition is impossible due to the second acquisition area.

In step S1, the other signal acquisition conditions may be automatically or manually set in addition to the first acquisition area, the second acquisition area, the first excitation area, and the second excitation area. The processing circuitry 51 then constructs an MRS pulse sequence based on the set signal acquisition conditions.

After step S1, the processing circuitry 51 acquires, through realization of the acquisition function 512, the first MR signal and the second MR signal by triaxial localization performed on the first acquisition area and the second acquisition area (step S2). Specifically, the processing circuitry 51 sends to the pulse sequence generator 29 the MRS pulse sequence for performing triaxial localization on the first acquisition area and the second acquisition area, and the pulse sequence generator 29 synchronously controls the gradient field power supply 21, the transmission circuitry 23, and the reception circuitry 25 in accordance with the MRS pulse sequence, and acquires MR signals emitted form the subject P. In MRS, various types of pre-scanning are performed before signal acquisition (main scan) by triaxial localization of the first acquisition area and the second acquisition area. A typical signal acquisition procedure by the pulse sequence generator 29 in MRS is as follows.
1. First, shimming fitted for a target acquisition area is performed. Calibration data for first-or higher order magnetic field non-uniformity correction is collected. Shimming may be performed through, for example, two-dimensional or three-dimensional SPGR (spoiled gradient echo), FASTMAP (fast automatic shimming technology by mapping along projections), FASTESTMAP (fast automatic shimming technology using echo-planar signal readout for mapping along projections), etc.
2. Next, center-frequency scanning fitted for a target acquisition area is performed. Calibration data for resonance frequency (zero-order correction values as explained above) estimation is collected by this scan.
3. Next, water-suppression calibration scan fitted for a target acquisition area is performed. Data for water suppression sequence adjustment for maximizing a water suppression performance is collected by this scan. A water suppression calibration scan can be performed through WET (water suppression enhanced through T1 effects), VAPOR (variable power and optimized relaxations delays), or another discretionarily selected method.
4. Next, water-reference scan fitted for a target acquisition area is performed. Apparatus output reference data is acquired by this scan. The apparatus output reference data means a sample in which the strength of the RF for water suppression is zero.
5. Then main scan fitted for the acquisition area is performed. An apparatus output sample is acquired by this scan. The apparatus output sample means a first MR signal or a second MR signal, which is a sample used for spectrum analysis. In this scan, the pulse sequence generator 29 selectively excites the first excitation area to acquire a first MR signal, and selectively excites the second excitation area to acquire a second MR signal before exciting the first excitation area once again, in accordance with the pulse sequence shown in FIG. 2. When the first and second excitation areas are made oblique, Gx, Gy, and Gz during RF pulse irradiation are rotated in accordance with a direction in which the first and second excitation areas are made oblique. The main scan is repeated for the number of times of integration (NEX).

The apparatus output sample (the first MR signal and the second MR signal) acquired in MR spectroscopy is strongly dependent on the calibration of the acquisition area. In other words, it is necessary to maximize the magnetic field non-uniformity correction and water suppression performance tailored to the acquisition area. The pulse sequence generator 29 dynamically switches a magnetic field non-uniformity correction value and a water suppression control value between the first acquisition area and the second acquisition area.

The switching of a magnetic field non-uniformity correction value is explained first. The processing circuitry 51 calculates, through realization of the setting function 511, a magnetic field non-uniformity correction value for each of the first acquisition area and the second acquisition area based on calibration data for correcting a first-order or higher magnetic field non-uniformity and the calibration data for a resonance frequency estimate. Specifically, the processing circuitry 51 calculates a magnetic field non-uniformity correction value as a coefficient for determining a strength of a first-order or second-order magnetic field. A calculation method may be but is not particularly limited to a least-squares method. Three components Gx, Gy, and Gz may be a strength of a first-order magnetic field, and five components GzGx, GxGy, GyGz, (GzGz−0.5* (GxGx+GyGy)), GxGx−GyGy may be a second-order magnetic field. The pulse sequence generator 29 dynamically switches the calculated magnetic field non-uniformity correction value in accordance with an acquisition area in which signal acquisition is performed. Only a magnetic field non-uniformity correction value for a strength of a first-order magnetic field may be used, or a magnetic field non-uniformity correction value for a strength of third-order or higher magnetic field may be used.

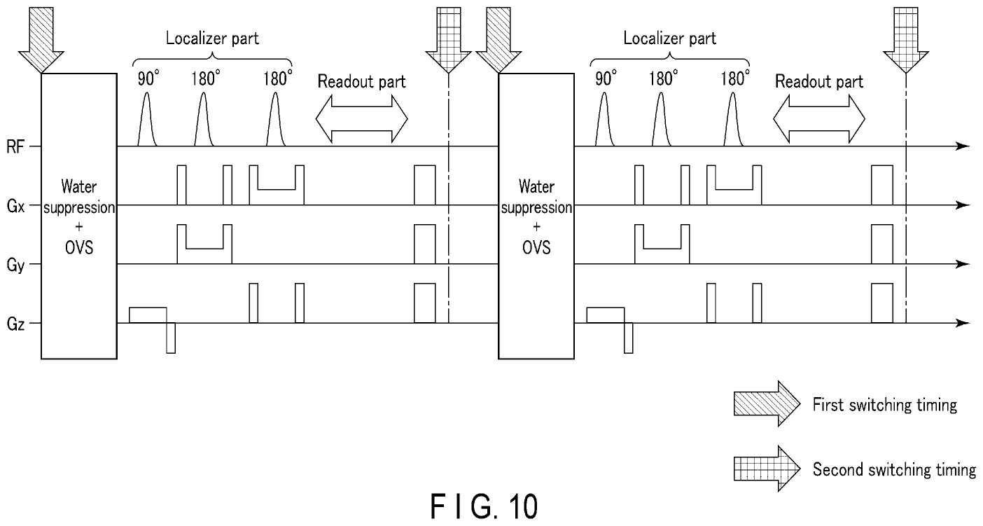

FIG. 10 is a diagram illustrating a timing of switching magnetic field non-uniformity correction values. The MRS pulse sequence shown in FIG. 10 is the same as that shown in FIG. 2. As described above, the pulse sequence generator 29 alternately repeats the signal acquisition in the first acquisition area and the signal acquisition in the second acquisition area. When the first and second excitation areas are made oblique, Gx, Gy, and Gz during RF pulse irradiation are rotated in accordance with a direction in which the first and second excitation areas are made oblique. The pulse sequence generator 29 alternately switches a first correction value relating to magnetic field non-uniformity correction for the first acquisition area and a second correction value relating to magnetic field non-uniformity correction for the second acquisition area before a magnetic field application to the first excitation area and before a magnetic field application to the second excitation area. Signal acquisition can be thereby achieved with a magnetic field non-uniformity correction suitable for each acquisition area, and it can be expected that the accuracy of acquired MR signals and spectra based thereon be improved.

As shown in FIG. 10, two types of timings for switching a magnetic field non-uniformity correction value are assumed. At the first switching timing, the magnetic field non-uniformity correction value is switched to a first correction value prior to the application of a water suppression pulse or an OVS pulse in the first MR signal acquisition sequence (hereinafter, the “first acquisition sequence”) to the first excitation area. Similarly, the magnetic field non-uniformity correction value is switched to a second correction value prior to the application of a water suppression pulse or an OVS pulse in the second MR signal acquisition sequence (hereinafter, the “second acquisition sequence”) to the second excitation area. At the second switching timing, the magnetic field non-uniformity correction value is switched to a first correction value subsequently to an application of a spoiler gradient field subsequent to an application of a readout gradient field in the second acquisition sequence performed immediately before the first acquisition sequence. Similarly, the magnetic field non-uniformity correction value is switched to a second correction value subsequently to an application of a spoiler gradient field subsequent to an application of a readout gradient field in the first acquisition sequence performed immediately before the second acquisition sequence.

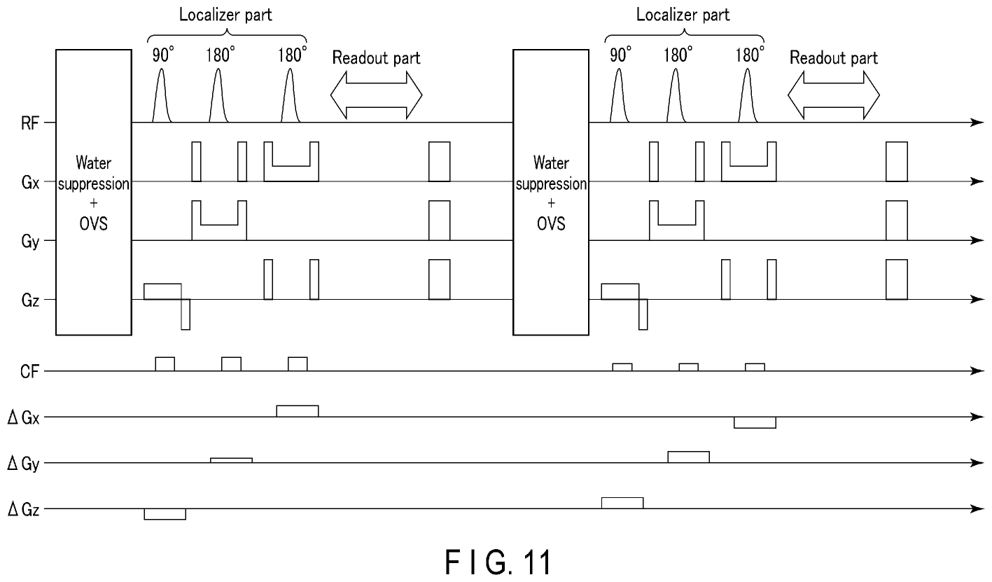

FIG. 11 is a diagram showing a timing of applying an offset magnetic field to be superimposed for non-uniform magnetic field correction. As shown in FIG. 11, “CF” represents a strength [Hz] of an offset magnetic field relating to a central frequency F0. The central frequency F0 is adjusted to adjust a static magnetic field B0. “ΔGx” represents a magnetic field gradient [Hz/m] of an offset magnetic field relating to a first-order X-direction magnetic field; “ΔGy” represents a magnetic field gradient [Hz/m] of an offset magnetic field relating to a first-order Y-direction magnetic field; and “ΔGz” represents a magnetic field gradient [Hz/m] of an offset magnetic field relating to a first-order Z-direction magnetic field. [Hz] may be expressed by “mT” or “G” instead. The strength of the magnetic gradient of the offset magnetic field is determined in accordance with a magnetic field non-uniformity correction value, and has a value smaller than the strength of a magnetic gradient of a gradient field, such as 1/10 or 1/100.

As shown in FIG. 11, the offset magnetic field relating to the central frequency FO is superimposed on a 90-degree excitation pulse, a first 180-degree refocusing pulse, and a second 180-degree refocusing pulse in the localizer part. The offset magnetic field relating to a first-order X-direction magnetic field is superimposed on the readout gradient field, the offset magnetic field relating to a first-order Y-direction magnetic field is superimposed on the phase encoding gradient field, and the offset magnetic field relating to a first-order Z-direction magnetic field is superimposed on the slice selective gradient field gradient field.

Next, the switching of a water suppression controlling value is explained. The processing circuitry 51 calculates, through realization of the setting function 511, a water-suppression controlling value for each of the first acquisition area and the second acquisition area based on data for adjusting the water suppression sequence. The water suppression controlling value is defined by a flip angle and/or a pulse interval of a water suppression pulse.

The water suppression controlling value is calculated by the following procedures, for example. First, the pulse sequence generator 29 acquires multiple MR signals respectively corresponding to multiple candidate values of water suppression controlling values by performing a water suppression calibration scan at the multiple candidate values for each of the first acquisition area and the second acquisition area. The candidate values of the water suppression controlling values may be determined randomly or based on past experiences. Subsequently, the processing circuitry 51 estimates an optimum value of the water suppression controlling value based on the acquired multiple MR signals for each of the first acquisition area and the second acquisition area. As an optimum value, for example, a value at which the strength of the water signal (an MR signal component originating from water) of the MR signal is weakest is estimated. Any method may be adopted as the method of estimating an optimum value, for example quadric function fitting. In this case, the processing circuitry 51 plots multiple MR signals on a graph in which a vertical axis represents a water signal strength value and a horizontal axis represents a water suppression controlling value, performs quadric function fitting on the multiple plot points, and determines a quadric function that best fits the plot points. The processing circuitry 51 selects the lowest point of the determined quadric function as an optimum value. A water suppression controlling value is thereby calculated for the first acquisition area and the second acquisition area. The fitting is not limited to a quadric function and may be performed with any function.

The water suppression controlling value can be dynamically switched at the time of a main scan in accordance with an acquisition area of a signal acquisition target. Specifically, the pulse sequence generator 29 alternately switches the first water suppression controlling value for the first acquisition area and the second water suppression controlling value for the second acquisition area before an application of a water suppression pulse for the first excitation area and before an application of a water suppression pulse for the second excitation area. It is thereby possible to achieve water suppression with a water suppression controlling value suitable for each acquisition area, and it can be expected that the accuracy of acquired MR signals and spectra based thereon be improved.

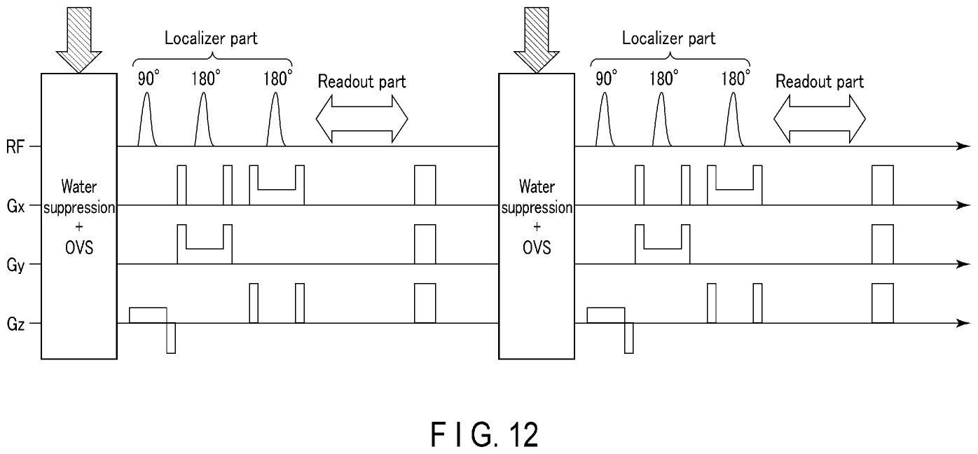

FIG. 12 is a diagram showing a timing of switching water-suppression controlling values. The MRS pulse sequence shown in FIG. 12 is the same as that shown in FIG. 2. As shown in FIG. 12, the pulse sequence generator 29 alternately repeats the signal acquisition in the first acquisition area and the signal acquisition in the second acquisition area. When the first and second excitation areas are made oblique, Gx, Gy, and Gz during RF pulse irradiation are rotated in accordance with a direction in which the first and second excitation areas are made oblique. The pulse sequence generator 29 switches the water suppression control value to a first water suppression control value before an application of a water suppression pulse for the first acquisition area, and to a second control value before an application of a water suppression pulse for the second acquisition area.

Next, the OVS that precedes the localizer part is explained. The OVS is a technique of applying a prepulse, such as a suppression pulse, etc. (hereinafter, “OVS pulse”) to an area other than the acquisition area and/or the excitation area so as to suppress mixing of an MR signal originating from these areas into an MR signal acquired by triaxial localization. The influence of OVS for the first acquisition area also affects the second acquisition area. For this reason, the processing circuitry 51 sets an OVS pulse application area at a position where the area does not overlap with the first acquisition area and the second acquisition area.

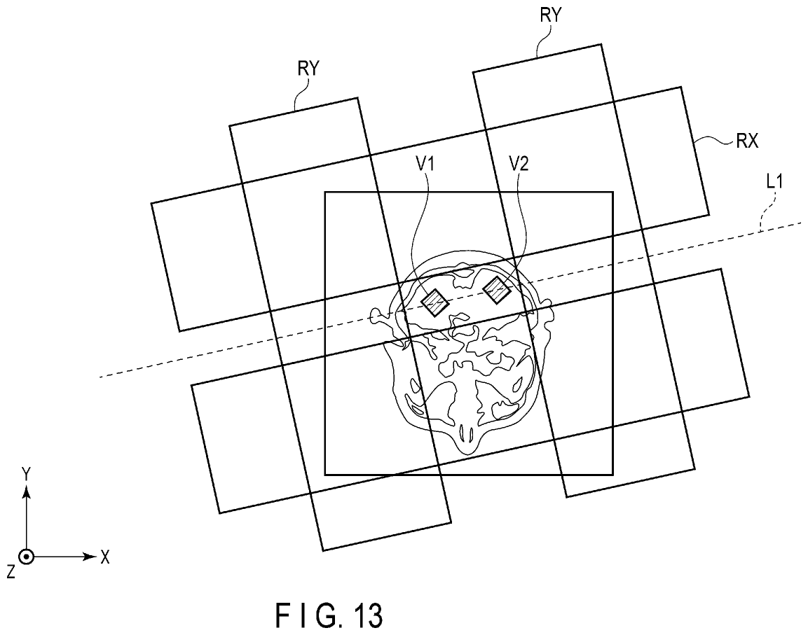

FIG. 13 is a diagram showing a positional relationship between an OVS pulse-applied area (hereinafter, an “OVS area”) RX, RY, and the acquisition areas V1 and V2. As shown in FIG. 13, the first acquisition area V1 and the second acquisition area V2 are set so as not to overlap with the second excitation area (not shown in FIG. 13) and the first excitation area (not shown in FIG. 13), respectively. The OVS areas RX and RY are set as a combination of multiple unit areas. A unit area is initially a band area parallel to the X axis, the Y axis, or the Z axis, and may be tilted independently from the oblique angle of the acquisition area. For example, as shown in FIG. 13, the unit area RX is a band area that does not overlap with the first acquisition area V1 and the second acquisition area V2 and is tilted by a discretionarily selected angle with respect to the X axis. The unit area RY is a band area that does not overlap with the first acquisition area V1 and the second acquisition area V2 and is tilted by a discretionarily selected angle with respect to the Y axis. Although not shown in FIG. 13, a unit area, which is a band area that does not overlap with the first acquisition area V1 and the second acquisition area V2 and is tilted by a discretionarily selected angle with respect to the Z axis, may be set. A sum area of these unit areas is set as an OVS area.

Specifically, as shown in FIG. 13, if there are two acquisition areas, the processing circuitry 51 connects the centers of the two acquisition areas V1 and V2 with a line L1, and sets the OVS area in an area RX that is parallel with the line L1 and not overlapping with the acquisition areas V1 and V2 and the plane RY orthogonal to the area RX.

If there are three or more acquisition areas, the processing circuitry 51 may set a rectangular area externally adjoining to all acquisition areas, and may set an OVS area in the area that does not intersect with the set rectangular area. If three directions are determined, it is possible to determine a suitable rectangular area based on a position of the acquisition area. The processing circuitry 51 can set and search angles at equal intervals as candidates and determine a suitable direction by repeating the operation of setting and searching angles at equal intervals in the vicinity of a minimal angle. A suitable direction means a direction in which a non-suppressed volume becomes maximum. If a direction is expressed by an angle, two angles, such as an angle defined by the X and Y directions and an angle defined by the X and Z directions, are sufficient.

After step S2, the processing circuitry 51 generates, through realization of the generation function 513, a first spectrum and a second spectrum based on a first MR signal and a second MR signal, respectively (step S3). Specifically, the processing circuitry 51 integrates NEX first MR signals. A noise can be reduced by the integration. The processing circuitry 51 generates a first spectrum by performing Fourier transform on the first MR signal after each integration operation. In the process of generating a first spectrum, various types of correction processing, such as zero-filling processing, phase correction, or a baseline correction, etc., may be performed. A first spectrum represents a signal distribution wherein a first MR signal strength is defined on a first axis and a chemical frequency is defined on a second axis orthogonal to the first axis. The second MR signal can be generated by a method similar to the method of generating the first MR signal.

After step S3, the processing circuitry 51 causes, through realization of the display control function 514, display of the first spectrum and a second spectrum on the display 53 (step S4). The operator is thus able to check the first spectrum and the second spectrum and, for example, compares an amount of substance of metabolites between the first acquisition area and the second acquisition area.

The operation of MRS according to the present embodiment is thus completed.

In the above-described embodiment, it is assumed that the acquisition area is defined by a single voxel. However, the present embodiment is not limited to this example. Each of the first acquisition area and the second acquisition area may be defined by a single voxel or multiple voxels.

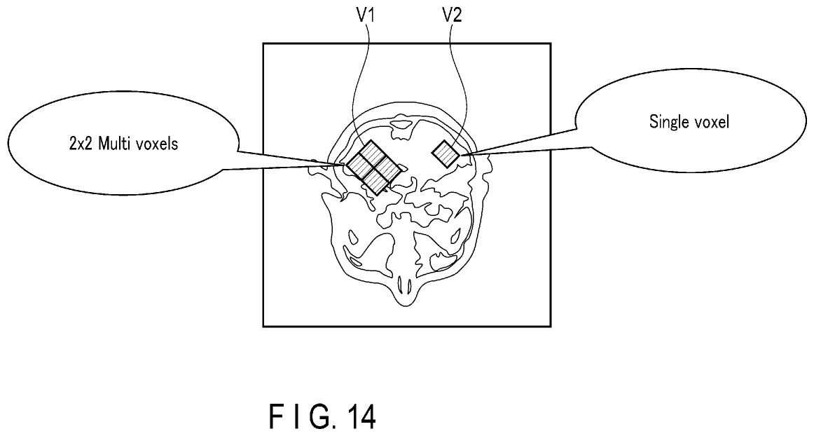

FIG. 14 is a diagram illustrating the size of an acquisition area. As shown in FIG. 14, the acquisition area V2 is defined by a single voxel. The acquisition area V1 is defined by multiple voxels, for example 2×2=4 voxels. Multiple voxels may include three-dimensionally multiple voxels with respect to the X axis, Y axis, and Z axis, for example 2×2×2=8 voxels. Not only the same number of voxels but different numbers of voxels may be arranged with respect to the X axis, Y axis, and Z axis.

In the foregoing embodiment, it is explained that the acquisition areas are set as a three-dimensional spatial area. However, the present embodiment is not limited to this example. The acquisition area may be set as a parallel-piped, two-dimensional spatial area that can be obtained by local excitation without selecting an area with respect to one of the X axis, Y axis, or Z axis.

According to the foregoing embodiments, a magnetic resonance signal acquisition apparatus 1 includes processing circuitry 51 and pulse sequence generator 29. The processing circuitry 51 sets the first acquisition area and the second acquisition area, which are a target for signal acquisition through triaxial localization, in such a manner that the first acquisition area does not three-dimensionally overlap with the second excitation area for the second acquisition area, and the second acquisition area does not three-dimensionally overlap with the first excitation area for the first acquisition area. The pulse sequence generator 29 acquires a first magnetic resonance signal by selectively exciting the first excitation area, and acquires a second magnetic resonance signal by selectively exciting the second excitation area.

According to the above-described configuration, it is possible to set one acquisition area so as not to three-dimensionally overlap with an excitation area for the other acquisition area, and it is thereby possible to improve the freedom in the setting of positions of acquisition areas. Furthermore, setting the position of an acquisition area in such a manner leads to reduction of a signal loss due to remaining magnetization of an excitation area of the other acquisition area, and an improvement in acquired signal quality is therefore expected. Since it is possible to acquire signals in an acquisition area during a recovery period of magnetization saturation in an excitation area for the other acquisition area, a total signal acquisition time for the first acquisition area and the second acquisition area can be shortened.

According to at least one of the above-described embodiments, in a signal acquisition method for multiple areas through triaxial localization, it is possible to shorten a signal acquisition time while freedom in the setting of a position of a signal acquisition area can be improved.

The term “processor” used in the above explanation indicates, for example, a circuit, such as a CPU, a GPU, or an application specific integrated circuit (ASIC), and a programmable logic device (for example, a simple programmable logic device (SPLD), a complex programmable logic device (CPLD), and a field programmable gate array (FPGA)). The processor realizes its function by reading and executing the program stored in the storage circuitry. The program may be directly incorporated into the circuit of the processor instead of being stored in the storage circuitry. In this case, the processor implements the function by reading and executing the program incorporated into the circuit. If the processor is for example an ASIC, on the other hand, the function is directly implemented in a circuit of the processor as a logic circuit, instead of storing a program in a storage circuit. Each processor of the present embodiment is not limited to a case where the processor is configured as a single circuit; a plurality of independent circuits may be combined into one processor to realize the function of the processor. In addition, a plurality of structural elements in FIG. 1 may be integrated into one processor to realize the function.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A magnetic resonance signal acquisition apparatus comprising:
processing circuitry configured to set a first acquisition area and a second acquisition area, which are a target for signal acquisition through triaxial localization, in such a manner that the first acquisition area does not three-dimensionally overlap with a second excitation area for the second acquisition area, and the second acquisition area does not three-dimensionally overlap with a first excitation area for the first acquisition area; and
pulse sequence generator configured to acquire a first magnetic resonance signal by selectively exciting the first excitation area and acquire a second magnetic resonance signal by selectively exciting the second excitation area.

2. The magnetic resonance signal acquisition apparatus according to claim 1, wherein
the processing circuitry sets, together with the first acquisition area, the first excitation area consisting of three band areas that are triaxially orthogonal to each other in the first acquisition area, and sets, together with the second acquisition area, the second excitation area consisting of three band areas that are triaxially orthogonal to each other in the second acquisition area.

3. The magnetic resonance signal acquisition apparatus according to claim 1, wherein
the processing circuitry is configured to:
display a user interface screen for setting the first acquisition area and the second acquisition area, on a display device; and
set the first acquisition area and the second acquisition area based on a user instruction that is input via the user interface screen.

4. The magnetic resonance signal acquisition apparatus according to claim 3, wherein
the processing circuitry displays the first acquisition area and the second acquisition area that are three-dimensionally tilted by a specific angle.

5. The magnetic resonance signal acquisition apparatus according to claim 4, wherein
the user interface screen has a GUI component for designating the specific angle.

6. The magnetic resonance signal acquisition apparatus according to claim 3, wherein
the processing circuitry is configured to:
set an initial position of the first acquisition area and an initial position of the second acquisition area based on a user instruction that is input via the user interface screen; and
automatically adjust, if the first acquisition area overlaps with the second excitation area and/or the second acquisition area overlaps with the first excitation area, an oblique angle of the first acquisition area and/or the second acquisition area so that the first acquisition area and/or the second excitation area do(es) not overlap with the second acquisition area and/or the first excitation area.

7. The magnetic resonance signal acquisition apparatus according to claim 3, wherein
the processing circuitry bars setting of the first acquisition area and the second acquisition area in an area in which signal acquisition is physically impossible.

8. The magnetic resonance signal acquisition apparatus according to claim 7, wherein
the signal acquisition impossible area is set in a spatial area that covers each of the first acquisition area and the second acquisition area and has a specific width.

9. The magnetic resonance signal acquisition apparatus according to claim 1, wherein
the pulse sequence generator alternately switches a first correction value relating to magnetic field non-uniformity correction for the first acquisition area and a second correction value relating to magnetic field non-uniformity correction for the second acquisition area before a magnetic field application to the first excitation area and before a magnetic field application to the second excitation area.

10. The magnetic resonance signal acquisition apparatus according to claim 9, wherein
the pulse sequence generator switches between the first correction value and the second correction value before an application of a water suppression pulse in an acquisition sequence of the first magnetic resonance signal and the second magnetic resonance signal for the first excitation area and the second excitation area or prior to an application of an outer volume suppression (OVS) pulse, or subsequent to an immediately preceding application of a spoiler gradient field that is subsequent to an application of a readout gradient field in an acquisition sequence of the second magnetic resonance signal and the first magnetic resonance signal in the second excitation area and the first excitation area.

11. The magnetic resonance signal acquisition apparatus according to claim 1, wherein
the pulse sequence generator alternately switches between the first control value for water suppression in the first acquisition area and a second control value for water suppression for the second acquisition area before an application of a water suppression pulse to the first excitation area and an application of a water suppression pulse to the second excitation area.

12. The magnetic resonance signal acquisition apparatus according to claim 11, wherein
the first control value and the second control value are a flip angle and/or a pulse interval of a water suppression pulse.

13. The magnetic resonance signal acquisition apparatus according to claim 1, wherein
the processing circuitry sets an application area of an outer volume suppression (OVS) pulse in a position that does not overlap with either the first acquisition area or the second acquisition area.

14. The magnetic resonance signal acquisition apparatus according to claim 1, wherein
the processing circuitry is configured to:
generate a first spectrum indicating a distribution of a signal strength of the first magnetic resonance signal for each chemical frequency based on the first magnetic resonance signal; and
generate a second spectrum indicating a distribution of a signal strength of the second magnetic resonance signal for each chemical frequency based on the second magnetic resonance signal.

15. The magnetic resonance signal acquisition apparatus according to claim 1, wherein
each of the first acquisition area and the second acquisition area are defined by a single voxel or multiple voxels.

16. The magnetic resonance signal acquisition apparatus according to claim 1, wherein p1 each of the first acquisition area and the second acquisition area is a three-dimensional spatial area.
